(19) United States
(12) Patent Application Publication
(10) Pub. No.: US 2019/0391497 A1
(43) Pub. Date: Dec. 26, 2019

(54) METHOD OF FORMING RESIST PATTERN

(71) Applicant: ZEON CORPORATION, Chiyoda-ku Tokyo (JP)

(72) Inventor: Nobuhiro SATO, Chiyoda-ku, Tokyo (JP)

(73) Assignee: ZEON CORPORATION, Chiyoda-ku Tokyo (JP)

(21) Appl. No.: 16/490,665

(22) PCT Filed: Feb. 21, 2018
(86) PCT No.: PCT/JP2018/006275

§ 371 Date: Sep. 3, 2019

(30) Foreign Application Priority Data
Mar. 29, 2017 (JP) 2017-065799

(51) Int. Cl. G03F 7/40; G03F 7/012; G03F 7/20; H01L 21/02; H01L 21/027

(52) U.S. Cl. CPC G03F 7/40; G03F 7/012; H01L 21/0273; H01L 21/02118; G03F 7/20

(57) ABSTRACT

Disclosed is a method of forming a resist pattern which comprises: forming a radiation-sensitive resin film using a resin liquid containing an alkali-soluble resin, a cross-linker component, and an organic solvent; exposing the radiation-sensitive resin film to form a cured film; developing the cured film to form a developed pattern; and applying post-development baking on the developed pattern to provide a resist pattern, wherein the alkali-soluble resin comprises 35% by mass or more and 90% by mass or less of a polyvinyl phenol resin, and a temperature of the post-development baking is 200° C. or higher.

### TECHNICAL FIELD

The present disclosure relates to methods of forming a resist pattern.

### BACKGROUND

In the fields of photolithography, methods of forming a desired resist pattern have been used which include the steps of cross-linking the resin in exposed areas by irradiation with actinic radiation (e.g., ultraviolet light, far ultraviolet light, excimer laser light, X-ray, electron beams, or extreme ultraviolet light) and removing non-exposed areas by utilizing the difference in solubility in developer between the exposed area and the non-exposed area.

Such methods of forming a resist pattern employ, for example, a procedure wherein a resin liquid containing an alkali-soluble resin, a cross-linker component and an organic solvent is prepared, a radiation-sensitive resin film obtained from the resin liquid is irradiated with actinic radiation to form a cured film, and the cured film is developed with an alkaline developer (see, e.g., PTLS 1 and 2).

PTLS 1 and 2 propose techniques for forming a resist pattern having excellent heat resistance as well as good reverse taper shape in cross section by devising the components in a resin liquid containing an alkali-soluble resin.

Resist patterns having a reverse taper shape in cross section can be suitably used for forming metal interconnection patterns by the lift-off method, as well as for forming electrically insulating partitions used for organic EL display devices.

### CITATION LIST

### Patent Literature

PTL 1: WO01/61410A1

PTL 2: JP2005316412A

### SUMMARY

### Technical Problem

However, the conventional methods described above may undesirably result in high amounts of the following residual components in the resist pattern formed: water derived for example from adsorbed water of resin, degraded resin and alkaline developer; and organic components derived for example from the organic solvent contained in the resin liquid.

When a resist pattern containing high amounts of such residual water and organic component is used to form a metal interconnection pattern by the lift-off method, a good interconnection pattern cannot be obtained due to gas generated by heat upon metal deposition on the resist pattern. Further, when such a resist pattern is used to form electrically insulating partitions, gas may be generated during the operation of an organic EL display device to adversely affect the performance of the device.

An object of the present disclosure is therefore to provide a method of forming a resist pattern, which enables formation of a resist pattern having a good reverse taper shape in cross section and having reduced amounts of residual water and residual organic component.

### Solution to Problem

The inventor has made extensive studies to solve the foregoing problem and established that a resist pattern having low amounts of both residual water and residual organic component and having a good reverse taper shape in cross section can be formed by heating a pattern, obtained after development, at a specific temperature or higher while using an alkali-soluble resin which comprises a polyvinyl phenol resin in an amount falling within a specific range. The inventor thus completed the present disclosure.

Specifically, the present disclosure aims to advantageously solve the foregoing problem and a disclosed method of forming a resist pattern includes: forming a radiation-sensitive resin film using a resin liquid containing an alkali-soluble resin, a cross-linker component, and an organic solvent; exposing the radiation-sensitive resin film to form a cured film; developing the cured film to form a developed pattern; and applying post-development baking on the developed pattern to provide a resist pattern, wherein the alkali-soluble resin comprises 35% by mass or more and 90% by mass or less of a polyvinyl phenol resin, and a temperature of the post-development baking is 200° C. or higher. By applying post-development baking on the developed pattern in an atmosphere at 200° C. or higher while using an alkali-soluble resin containing 35% by mass or more and 90% by mass or less of a polyvinyl phenol resin as described above for the formation of a resist pattern using an alkali-soluble resin, it is possible to form a resist pattern having a good reverse taper shape in cross section and to reduce the residual water and residual organic component in the resist pattern.

The term “alkali-soluble” as used herein for a resin means that the insoluble fraction is less than 0.1% by mass when the resin is dissolved in a solution of pH 8 or higher.

The term “cross-linker component” as used herein refers to a component capable of cross-linking an alkali-soluble resin by irradiation (exposure) with actinic radiation and heat treatment (post-exposure baking) which is optionally carried out after exposure and before development.

The term “reverse taper shape” as used herein encompasses not only a standard taper shaper composed of inclined surfaces converging toward the taper apex, but also an overhang structure wherein the open area at the resist surface is smaller than the open area at the resist bottom.

In the disclosed method for forming a resist pattern, it is preferred that the temperature of the post-development baking is 400° C. or lower. When the temperature of the post-development baking is 400° C. or lower, it is possible to sufficiently reduce the residual water in the resulting resist pattern, as well as to limit thermal shrinkage of the resist pattern to thereby allow its cross section to maintain a good reverse taper shape.

In the disclosed method for forming a resist pattern, it is preferred that the temperature of the post-development baking is 220° C. or higher. When the temperature of the post-development baking is 220° C. or higher, it is possible to further reduce the residual water and residual organic component in the resulting resist pattern.

In the disclosed method for forming a resist pattern, it is preferred that the post-development baking is carried out in an inert gas atmosphere. When the post-development baking is carried out in an inert gas atmosphere, it is possible to further reduce the residual water in the resulting resist pattern.

In the disclosed method for forming a resist pattern, it is preferred that the inert gas is nitrogen. When the post-development baking is carried out in a nitrogen atmosphere, it is possible to further reduce the residual water in the resulting resist pattern.

In the disclosed method for forming a resist pattern, it is preferred that the resin liquid further comprises an actinic radiation absorbing compound. When a resin liquid containing an actinic radiation absorbing compound is used, it is possible to more easily form a resist pattern having a reverse taper shape in cross section.

The term “actinic radiation absorbing compound” as used herein refers to a compound having at least one maximum absorption wavelength λₘₐₓ in any wavelength range from 13.5 nm to 500 nm.

### Advantageous Effect

According to the present disclosure, it is possible to provide a method of forming a resist pattern, which enables formation of a resist pattern having a good reverse taper shape in cross section and having reduced amounts of residual water and residual organic component.

### DETAILED DESCRIPTION

Embodiments of the present disclosure will be described in detail below. The disclosed method of forming a resist pattern may allow for favorable production of a resist pattern having a reverse taper shape in cross section and can be used for example in semiconductor device manufacturing processes and for the formation of electrically insulating partitions of organic EL display elements.

The disclosed method of forming a resist pattern includes at least the steps of: forming a radiation-sensitive resin film using a resin liquid which comprises 35% by mass or more and 90% by mass or less of a polyvinyl phenol resin (radiation-sensitive resin film forming step); exposing the radiation-sensitive resin film to form a cured film (cured film forming step); developing the cured film to form a developed pattern (developing step); and applying post-development baking on the developed pattern (post-development baking step).

Because the disclosed method of forming a resist pattern applies post-development baking on the developed pattern at 200° C. or higher while using an alkali-soluble resin which comprises 35% by mass or more and 90% by mass or less of a polyvinyl phenol resin, it is possible to form a resist pattern having reduced amounts of residual water and residual organic component and having a good reverse taper shape in cross section.

<Radiation-Sensitive Resin Film Forming Step>

In the radiation-sensitive resin film forming step, a radiation-sensitive resin film is formed using a resin liquid which comprises an alkali-soluble resin, a cross-linker component and an organic solvent and which optionally comprises an actinic radiation absorbing compound and any known additives.

<Alkali-Soluble Resin>

In the disclosed method of forming a resist pattern, the resin liquid needs to comprise a polyvinyl phenol resin as the alkali-soluble resin. The resin liquid may comprise alkali-soluble resins other than the polyvinyl phenol resin (other alkali-soluble resins).

[Polyvinyl Phenol Resin]

Examples of polyvinyl phenol resins include homopolymers of vinyl phenol and copolymers of vinyl phenol and monomers copolymerizable with vinyl phenol. Examples of monomers copolymerizable with vinylphenol resins include isopropenylphenol, acrylic acid, methacrylic acid, styrene, maleic anhydride, maleic acid imide, and vinyl acetate. Preferred polyvinyl phenol resins are homopolymers of vinylphenol, with homopolymers of p-vinylphenol being more preferred.

The average molecular weight of the polyvinyl phenol resin is preferably 1,000 or more, more preferably 1,500 or more, and still more preferably 2,000 or more, but preferably 20,000 or less, more preferably 15,000 or less, and even more preferably 10,000 or less, in monodisperse polystyrene equivalent weight-average molecular weight (Mw) as measured by GPC. When the weight-average molecular weight of the polyvinyl phenol resin is 1,000 or more, the molecular weight of the resin constituting the exposed areas sufficiently increases by exposure (and optional post-exposure baking), allowing the exposed areas to have sufficiently reduced solubility in alkaline developer. Further, in this case, it is possible to limit thermal shrinkage of the resulting resist pattern to thereby allow its cross section to maintain a good reverse taper shape. On the other hand, when the average molecular weight of the polyvinyl phenol resin is 20,000 or less, it is possible to obtain a good resist pattern by ensuring that the exposed area and non-exposed area have different solubilities in alkaline developer.

The weight-average molecular weight of the polyvinyl phenol resin can be controlled to fall within a desired range by adjusting the synthesis conditions (e.g., the amount of the polymerization initiator and the reaction time at the time of synthesis).

The proportion of the polyvinyl phenol resin in the alkali-soluble resin needs to be 35% by mass or more and 90% by mass or less, preferably 40% by mass or more, more preferably 45% by mass or more, even more preferably 50% by mass or more, and particularly preferably 55% by mass or more, but preferably 85% by mass or less, and more preferably 80% by mass or less. If the proportion of the polyvinyl phenol resin in the alkali-soluble resin is less than 35% by mass, it is not possible to sufficiently reduce the residual water in the resist pattern. Further, in this case, the amount of the residual organic component may increase, and there is a concern that post-development baking causes such problems as significant shrinkage of resist pattern line width and/or inability of the resist pattern to maintain a reverse taper shape. On the other hand, if the proportion of the polyvinyl phenol resin in the alkali-soluble resin exceeds 90% by mass, it is not possible to favorably produce a resist pattern having a reverse taper shape in cross section due to generation of abnormal protrusions on sidewalls of the resist pattern.

[Other Alkali-Soluble Resins]

Alkali-soluble resins other than the polyvinyl phenol resins are not particularly limited and examples thereof include novolac resins, polyvinyl alcohol resins, resol resins, acrylic resins, styrene-acrylic acid copolymer resins, hydroxystyrene polymer resins, and polyvinyl hydroxybenzoate. These resins may be used singly in combination of two or more kinds. Preferred other alkali-soluble resins are novolac resins from the viewpoint of preventing the generation of abnormal protrusions on sidewalls of the resist pattern.

Novolac resins can be obtained for example by reacting phenols with aldehydes or ketones in the presence of acidic catalyst (e.g., oxalic acid).

Examples of phenols which may be used for the preparation of novolac resins include phenol, ortho-cresol, meta-cresol, para-cresol, 2,3-dimethylphenol, 2,5-dimethylphenol, 3,4-dimethylphenol, 3,5-dimethylphenol, 2,4-dimethylphenol, 2,6-dimethylphenol, 2,3,5-trimethylphenol, 2,3,6-trimethylphenol, 2-t-butylphenol, 3-t-butylphenol, 4-t-butylphenol, 2-methylresorcinol, 4-methylresorcinol, 5-methylresorcinol, 4-t-butylcatechol, 2-methoxyphenol, 3-methoxyphenol, 2-propylphenol, 3-propylphenol, 4-propylphenol, 2-isopropylphenol, 2-methoxy-5-methylphenol, 2 t-butyl-5-methylphenol, thymol, and isothymol. These phenols may be used singly in combination of two or more kinds.

Examples of aldehydes which may be used for the preparation of novolac resins include formaldehyde, formalin, paraformaldehyde, trioxane, acetaldehyde, propylaldehyde, benzaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-chlorobenzaldehyde, m-chlorobenzaldehyde, p-chlorobenzaldehyde, o-methylbenzaldehyde, m-methylbenzaldehyde, p-methylbenzaldehyde, p-ethylbenzaldehyde, p-n-butylbenzaldehyde, and terephthalaldehyde.

Examples of ketones which may be used for the preparation of novolac resins include acetone, methyl ethyl ketone, diethyl ketone, and diphenyl ketone.

These aldehyes and ketones may be used singly in combination of two or more kinds.

Preferred novolac resins are those obtained by condensation reaction of a combination of metacresol and paracresol (phenols) with formaldehyde, formalin or paraformaldehyde. Such novolac resins allow for easily control of the molecular weight distribution of the constituent polymer, so that the sensitivity of a radiation-sensitive resin film formed from a resin liquid containing the novolac resin to active radiation can be easily controlled. The ratio by mass of metacresol to paracresol for preparation is preferably 80:20 to 20:80, and more preferably 70:30 to 40:60.

The average molecular weight of the novolac resin is preferably 1,000 or more, more preferably 2,500 or more, and even more preferably 3,000 or more, but preferably 10,000 or less, more preferably 7,000 or less, and even more preferably 6000 or less, in monodisperse polystyrene equivalent weight-average molecular weight (Mw) as measured by GPC. When the weight-average molecular weight of the novolac resin is 1,000 or more, the molecular weight of the resin constituting the exposed areas sufficiently increases by exposure (and optional post-exposure baking), allowing the exposed areas to have sufficiently reduced solubility in alkaline developer. On the other hand, when the average molecular weight of the novolac resin is 10,000 or less, it is possible to obtain a good resist pattern by ensuring that the exposed area and non-exposed area have different solubilities in alkaline developer.

The weight-average molecular weight of the novolac resin can be controlled to fall within a desired range by adjusting the synthesis conditions (e.g., the amounts of aldehydes and ketones and the reaction time at the time of synthesis).

The proportion of the novolac resin in the alkali-soluble resin is preferably 10% by mass or more, more preferably 15% by mass or more, and even more preferably 20% by mass or more, but 65% by mass or less, preferably 60% by mass or less, more preferably 55% by mass or less, even more preferably 50% by mass or less, and particularly preferably 45% by mass or less. When the proportion of the novolac resin in the alkali-soluble resin is 10% by mass or more, it is possible to prevent the generation of abnormal protrusions on sidewalls of the resist pattern. On the other hand, when the proportion of the novolac resin in the alkali-soluble resin is 65% by mass or less, it is possible to ensure a sufficient proportion of the polyvinyl phenol resin in the alkali-soluble resin, so that the residual water and residual organic component in the resist pattern can be sufficiently reduced. Further, in this case, there is no concern that that post-development baking causes such problems as significant shrinkage of resist pattern line width and/or inability of the resist pattern to maintain a reverse taper shape.

<Cross-Linker Component>

As described above, the cross-linker component is a component capable of cross-linking the alkali-soluble resin by exposure and post-exposure baking which is optionally carried out. By the action of the cross-linker component, a cross-linked structure of the alkali-soluble resin is formed in exposed areas of a radiation-sensitive resin film formed from a resin liquid. With increases in the molecular weight of the alkali-soluble resin in the exposed areas, the exposed areas show a much lower dissolution rate in alkaline developer than non-exposed areas.

Examples of usable cross-linker components include those consisting of a combination of two or more different components, such as the following combination (1) or (2):

(1) A combination of a photopolymerization initiator (e.g., benzophenone derivative, benzoin derivative, or benzoin ether derivative) that generates a radical upon exposure, a compound having an unsaturated hydrocarbon group to be polymerized by the radical (e.g., pentaerythritol tetra(meth)acrylate), and an optional sensitizer to enhance the efficiency of the photoreaction; and

(2) A combination of a compound that generates an acid upon exposure (hereinafter referred to as “photoacid generator”) and a compound that cross-links the alkali-soluble resin by means of the generated acid as a catalyst (hereinafter referred to as “acid-catalyzed cross-linker”).

From the viewpoint of its good compatibility with the alkali-soluble resin and its capability of forming a radiation-sensitive resin film having good sensitivity to actinic radiation when combined with the alkali-soluble resin, the combination (2) (combination of an acid generator and an acid-catalyzed cross-linker) is preferred as the cross-linker component.

[Photoacid Generator]

Photoacid generators are not particularly limited as long as they are substances that generate an acid (Bronsted acid or Lewis acid) upon exposure in the cured film forming step described later. Examples of usable phoacid generators include onium salt compounds, halogenated organic compounds, quinonediazide compounds, sulfone compounds, organic acid ester compounds, organic acid amide compounds, organic acid imide compounds, and photoacid generators other than the foregoing.

These photoacid generators can be suitably selected from the viewpoint of spectral sensitivity according to the wavelength of the light source used to expose the pattern.

—Onium Salt Compounds—

Examples of onium salt compounds include diazonium salts, ammonium salts, iodonium salts (e.g., diphenyliodonium triflate), sulfonium salts (e.g., triphenylsulfonium triflate), phosphonium salts, arsonium salts, and oxonium salts.

—Halogenated Organic Compounds—

Examples of halogenated organic compounds include halogen-containing oxadiazole compounds, halogen-containing triazine compounds, halogen-containing acetophenone compounds, halogen-containing benzophenone compounds, halogen-containing sulfoxide compounds, halogen-containing sulfone compounds, halogen-containing thiazole compounds, halogen-containing oxazole compounds, halogen-containing triazole compounds, halogen-containing 2-pyrone compounds, other halogen-containing heterocyclic compounds, halogen-containing aliphatic hydrocarbon compounds, halogen-containing aromatic hydrocarbon compounds, and sulphenyl halide compounds.

Specific examples of halogenated organic compounds include tris(2,3-dibromopropyl)phosphate, tris(2,3-dibromo-3-chloropropyl)phosphate, tetrabromochlorobutane, 2-[2-(3,4-dimethoxyphenyl)ethenyl]-4,6-bis(trichloromethyl)-S-triazine, 2-[2-(4-methoxyphenyl)ethenyl]-4,6-bis(trichloromethyl)-S-triazine, hexachlorobenzene, hexabromobenzene, hexabromocyclododecane, hexabromocyclododecene, hexabromobiphenyl, allyltribromophenylether, tetrachlorobisphenol A, tetrabromobisphenol A, bis(chloroethyl)ether of tetrachlorobisphenol A, bis(bromoethyl)ether of tetrabromobisphenol A, bis(2,3-dichloropropyl)ether of bisphenol A, bis(2,3-dibromopropyl)ether of bisphenol A, bis(2,3-dichloropropyl)ether of tetrachlorobisphenol A, bis(2,3-dibromopropyl)ether of tetrabromobisphenol A, tetrachlorobisphenol S, tetrabromobisphenol S, bis(chloroethyl)ether of tetrachlorobisphenol S, bis(bromoethyl)ether of tetrabromobisphenol S, bis(2,3-dichloropropyl)ether of bisphenol S, bis(2,3-dibromopropyl)ether of bisphenol S, tris(2,3-dibromopropyl)isocyanurate, 2,2-bis(4-hydroxy-3,5-dibromophenyl)propane, and 2,2-bis(4-(2-hydroxyethoxy)-3,5-dibromophenyl)propane.

—Quinonediazide Compounds—

Examples of quinonediazide compounds include sulfonic acid esters of quinonediazide derivatives, such as 1,2-benzoquinonediazide-4-sulfonic acid ester, 1,2-naphthoquinonediazide-4-sulfonic acid ester, 1,2-naphthoquinonediazide-5-sulfonic acid ester, 2,1-naphthoquinonediazide-4-sulfonic acid ester, and 2,1-benzoquinonediazide-5-sulfonic acid ester; and sulfonic acid chlorides of quinonediazide derivatives, such as 1,2-benzoquinone-2-diazide-4-sulfonic acid chloride, 1,2-naphthoquinone-2-diazide-4-sulfonic acid chloride, 1,2-naphthoquinone-2-diazide-5-sulfonic acid chloride, 1,2-naphthoquinone-1-diazide-6-sulfonic acid chloride, and 1,2-benzoquinone-1-diazide-5-sulfonic acid chloride.

—Sulfone Compounds—

Examples of sulfone compounds include sulfone compounds and disulfone compounds, which have an unsubstituted or symmetrically or asymmetrically substituted alkyl group, alkenyl group, aralkyl group, aromatic group or heterocyclic group.

—Organic Acid Ester Compounds—

Examples of organic acid ester compounds include carboxylic acid esters, sulfonic acid esters, and phosphoric acid esters.

—Organic Acid Amide Compounds—

Examples of organic acid amide compound include carboxylic acid amides, sulfonic acid amides, and phosphoric acid amides.

—Organic Acid Imide Compounds—

Examples of organic acid imide compounds include carboxylic acid imides, sulfonic acid imides, and phosphoric acid imides.

—Other Photooxidants—

Examples of photooxidants other than the onium salts, halogenated organic compounds, quinonediazide compounds, sulfone compounds, organic acid ester compounds, organic acid amide compounds, and organic acid imide compounds described above include cyclohexylmethyl(2-oxocyclohexyl)sulfonium trifluoromethanesulfonate, dicyclohexyl(2-oxocyclohexyl)sulfonium trifluoromethanesulfonate, 2-oxocyclohexyl(2-norbornyl)sulfonium trifluoromethanesulfonate, 2-cyclohexylsulfonylcyclohexanone, dimethyl(2-oxocyclohexyl)sulfonium trifluoromethanesulfonate, triphenylsulfonium trifluoromethanesulfonate, diphenyliodonium trifluoromethanesulfonate, N-hydroxysuccinimide trifluoromethanesulfonate, and phenyl p-toluene sulfonate.

These photoacid generators may be used singly or in combination of two or more. Preferred are halogenated organic compounds, with halogen-containing triazine compounds being more preferred.

The resin liquid preferably comprises the photoacid generator in an amount of 0.1 parts by mass or more and 10 parts by mass or less, more preferably 0.3 parts by mass or more and 8 parts by mass or less, and even more preferably 0.5 parts by mass or more and 5 parts by mass or less, per 100 parts by mass of the alkali-soluble resin. When the amount of the photoacid generator is 0.1 parts by mass or more per 100 parts by mass of the alkali-soluble resin, it is possible to allow cross-linking of the alkali-soluble resin to proceed favorably by exposure. On the other hand, when the amount of the photoacid generator is 10 parts by mass or less per 100 parts by mass of the alkali-soluble resin, it is possible to limit degradation of the cross-sectional shape of the resist pattern, which is caused by cross-linking of non-exposed portions due to generation of excessive acid.

[Acid-catalyzed cross-linker]

Acid-catalyzed cross-linkers are compounds (acid-sensitive substances) that may crosslink the alkali-soluble resin by means of an acid generated upon exposure from the photoacid generator. Examples of such acid-catalyzed cross-linkers include alkoxymethylated urea resins, alkoxymethylated melamine resins, alkoxymethylated urone resins, alkoxymethylated glycoluril resins, alkoxymethylated amino resins, alkyletherified melamine resins, benzoguanamine resins, alkyletherified benzoguanamine resins, urea resins, alkyletherified urea resins, urethane-formaldehyde resins, resol type phenol formaldehyde resins, alkyletherified resol type phenol formaldehyde resins, and epoxy resins.

These acid-catalyzed cross-linkers may be used singly or in combination of two or more kinds. Preferred are alkoxymethylated melamine resins. Specific examples of alkoxymethylated melamine resins include methoxymethylated melamine resins, ethoxymethylated melamine resins, n-propoxymethylated melamine resins, and n-butoxymethylated melamine resins. From the viewpoint of enhancing the resolution of the resist pattern, methoxymethylated melamine resins such as hexamethoxymethylmelamine are particularly preferred.

The resin liquid preferably comprises the acid-catalyzed cross-linker in an amount of 0.5 parts by mass or more and 60 parts by mass or less, more preferably 1 part by mass or more and 50 parts by mass or less, and even more preferably 2 parts by mass or more and 40 parts by mass or less, per 100 parts by mass of the alkali-soluble resin. When the amount of the acid-catalyzed cross-linker is 0.5 parts by mass or more per 100 parts by mass of the alkali-soluble resin, it is possible to allow cross-linking of the alkali-soluble resin to proceed favorably by exposure. It is thus possible to limit deformation (e.g., swelling or meandering) of the resist pattern while preventing reductions in the film retention rate in exposed areas of the resist pattern by development using an alkaline developer. On the other hand, when the amount of the acid-catalyzed cross-linker is 60 parts by mass or less per 100 parts by mass of the alkali-soluble resin, it is possible to ensure the resolution of the resist pattern.

<Actinic Radiation Absorbing Compound>

Actinic radiation absorbing compounds are a component capable of absorbing actinic radiation applied in the cured film forming step. When the resin solution contains an actinic radiation absorbing compound, it is possible to more easily form a resist pattern having a good reverse taper shape in cross section.

The cross-sectional shape of a resist pattern is also influenced as a result of the actinic radiation, applied to the radiation-sensitive resin film in the cured film forming step, passing through the radiation-sensitive resin film and being reflected at the surface of the substrate or other member. When an actinic radiation absorbing compound is blended into the resin liquid, the actinic radiation absorbing compound present in the radiation-sensitive resin film absorbs actinic radiation reflected at the surface of the substrate or other member, so that the cross-sectional shape of the resist pattern can be favorably controlled. The acid generated by application of actinic radiation may diffuse through the radiation-sensitive resin film and cause cross-linking reactions also in non-exposed areas particularly when the above-described combination of a photoacid generator and an acid-catalyzed cross-linker is used as the cross-linker component. However, when an actinic radiation absorbing compound is present in the radiation-sensitive resin film, it is possible to favorably control the cross-sectional shape of the resist pattern by limiting excessive cross-linking reactions.

Examples of actinic radiation absorbing compounds include bisazide compounds; natural compounds such as azo dyes, methine dyes, azomethine dyes, curcumin, and xanthone; cyanovinylstyrene compounds; 1-cyano-2-(4-dialkylaminophenyl)ethylenes; p-(halogen-substituted phenylazo)-dialkylaminobenzenes; 1-alkoxy-4-(4′-N,N-dialkylaminophenylazo)benzenes; dialkylamino compounds; 1,2-dicyanoethylene; 9-cyanoanthracene; 9-anthrylmethylene malononitrile; N-ethyl-3-carbazolylmethylene malononitrile; and 2-(3,3-dicyano-2-propenylidene)-3-methyl-1,3-thiazoline.

Actinic radiation absorbing compounds may be used singly or in combination of two or more kinds. Preferred actinic radiation absorbing compounds are bisazide compounds, with bisazide compounds having an azide group at both terminals being more preferred. Particularly preferred bisazide compounds are those having at least one maximum absorption wavelength λₘₐₓ in any wavelength range from 200 nm to 500 nm.

Examples of bisazide compounds suitably used as actinic radiation absorbing compounds include 4,4′-diazidechalcone, 2,6-bis(4′-azidobenzal)cyclohexanone, 2,6-bis(4′-azidobenzal)-4-methylcyclohexanone, 2,6-bis(4′-azidobenzal)-4-ethylcyclohexanone, sodium 4,4′-diazidestilbene-2,2′-disulfonate, 4,4′-diazidediphenylsulfide, 4,4′-diazidebenzophenone, 4,4′-diazidediphenyl, 2,7-diazidefluorene, and 4,4′-diazidephenylmethane.

The resin liquid preferably comprises the actinic radiation absorbing compound in an amount of 0.1 parts by mass or more, more preferably 0.2 parts by mass or more, and even more preferably 0.3 parts by mass or more, but preferably 10 parts by mass or less, more preferably 8 parts by mass or less, and even more preferably 5 parts by mass or less, per 100 parts by mass of the alkali-soluble resin. When the amount of the actinic radiation absorbing compound falls within the range described above, it is possible to more easily form a resist pattern having a good reverse taper shape in cross section.

<Additives>

Known additives optionally added in the resin liquid are not particularly limited and examples thereof include those described JP2005-316412A. Additives may be used singly or in combination of two or more kinds. In order to ensure the dispersibility of the components in the resin liquid, it is preferred to use surfactants as additives. Further, in order to ensure the storage stability of the resin liquid, it is preferred to use nitrogen-containing basic compounds such as triethanolamine as additives.

<Organic Solvent>

Organic solvents used for the resin liquid are not particularly limited as long as the components described above can be dissolved and/or dispersed therein. Examples of organic solvents include alcohols such as n-propyl alcohol, i-propyl alcohol, n-butyl alcohol, and cyclohexyl alcohol; ketones such as acetone, methyl ethyl ketone, methyl isobutyl ketone, cyclopentanone, and cyclohexanone; esters such as propyl formate, butyl formate, ethyl acetate, propyl acetate, butyl acetate, isoamyl acetate, methyl propionate, ethyl propionate, methyl butyrate, ethyl butyrate, methyl lactate, ethyl lactate, ethyl ethoxypropionate, and ethyl pyruvate; cyclic ethers such as tetrahydrofuran and dioxane; cellosolves such as methyl cellosolve, ethyl cellosolve, and butyl cellosolve; cellosolve acetates such as ethyl cellosolve acetate, propyl cellosolve acetate, and butyl cellosolve acetate; alcohol ethers such as ethylene glycol dimethyl ether, ethylene glycol diethyl ether, ethylene glycol monomethyl ether, and ethylene glycol monoethyl ether; propylene glycols such as propylene glycol, propylene glycol monomethyl ether acetate, propylene glycol monoethyl acetate, and propylene glycol monobutyl ether; diethylene glycols such as diethylene glycol monomethyl ether, diethylene glycol monoethyl ether, diethylene glycol dimethyl ether, and diethylene glycol diethyl ether; lactones such as γ-butyrolactone; halogenated hydrocarbons such as trichloroethylene; aromatic hydrocarbons such as toluene and xylene; and other polar organic solvents such as dimethylformamide and N-methylacetamide.

Organic solvents may be used singly in combination of two or more kinds. Preferred are propylene glycols, with propylene glycol monomethyl ether acetate being more preferred.

<Preparation of Resin Liquid>

The resin liquid can be prepared by mixing the above-described alkali-soluble resin, cross-linker component, actinic radiation absorbing compound, organic solvent, and optional additives. Mixing methods are not particularly limited and any known mixing methods can be used.

<Formation of Radiation-Sensitive Resin Film>

Methods of forming a radiation-sensitive resin film using the resin liquid described above are not particularly limited. For example, a radiation-sensitive resin film can be obtained by applying the resin liquid onto a substrate, followed by heating and drying (pre-exposure baking) of the resulting coating film. The thickness of the resulting radiation-sensitive resin film is not particularly limited, but is preferably 0.1 μm or more and 15 μm or less.

[Substrate]

Substrates are not particularly limited as long as common substrates which can be used as semiconductor substrates are used. For example, silicon substrates, glass substrates, substrates with ITO film, substrates with chromium film, and resin substrates may be used.

[Coating]

Application of the resin liquid onto a substrate can be accomplished by common coating methods such as, for example, spin coating, spray coating, brush coating, and dip coating.

[Pre-Exposure Baking]

The temperature of the pre-exposure baking can be, for example, 80° C. or higher and 120° C. or lower, and the pre-exposure baking time can be, for example, 10 seconds or more and 200 seconds or less.

(Cured Film Forming Step)

In the cured film forming step, a cured film is obtained by exposing the radiation sensitive resin film obtained in the radiation-sensitive resin film so as to draw a desired pattern and by optionally carrying out post-exposure baking where necessary.

<Exposure>

Actinic radiation used for exposure is, for example, ultraviolet light, far ultraviolet light, excimer laser light, X-ray, electron beams, or extreme ultraviolet light, preferably with a wavelength of 13.5 nm or more and 450 nm or less. Exposure light sources are not particularly limited as long as they are light sources capable of applying actinic radiation and examples thereof include known exposure devices such as semiconductor laser devices, metal halide lamps, high pressure mercury lamps, excimer laser (KrF, ArF, F₂) irradiation devices, X-ray exposure devices, electron beam exposure devices, and extreme ultraviolet exposure devices.

<Post-Exposure Baking>

Particularly when the combination of a photoacid generator and an acid-catalyzed cross-linker is used as the cross-linker component, post-exposure baking is preferably carried out on the exposed radiation-sensitive resin film in order to accelerate the cross-linking reactions. The temperature of the post-exposure baking can be, for example, 100° C. or higher and 130° C. or below, and the post-exposure baking time can be, for example, 10 seconds or more and 200 seconds or less.

(Developing Step)

In the developing step, the cured film obtained in the cured film forming step is brought into contact with an alkaline developer to develop the cured film and form a developed pattern on a workpiece such as a substrate.

<Alkaline Developer>

Alkaline developers used in the developing step are not particularly limited. Alkaline aqueous solutions having a pH of 8 or higher can be advantageously used.

Alkaline components used to prepare aqueous alkaline solutions are not particularly limited and examples thereof include inorganic alkalis such as sodium hydroxide, potassium hydroxide, sodium silicate and ammonia; primary amines such as ethylamine and propylamine; secondary amines such as diethylamine and dipropylamine; tertiary amines such as trimethylamine and triethylamine; alcohol amines such as diethylethanolamine and triethanolamine; and quaternary ammonium hydroxides such as tetramethylammonium hydroxide, tetraethylammonium hydroxide, triethylhydroxymethylammonium hydroxide, and trimethylhydroxyethyl ammonium hydroxide. These alkaline components may be used singly or in combination of two or more kinds.

Water-soluble organic solvents such as methyl alcohol, ethyl alcohol, propyl alcohol and ethylene glycol, surfactants, dissolution inhibitors for resins, and other agents may be optionally added to aqueous alkaline solutions where necessary.

<Contact with Alkaline Developer>

Methods of developing the radiation-sensitive resin film by contacting it with an alkaline developer are not particularly limited, and common developing methods such as paddle development, spray development or dip development can be used. Any known conditions can also be used for the development time and development temperature.

(Post-Development Baking Step)

In the post-development baking step, post-development baking is applied on the developed pattern obtained in the developing step to provide a resist pattern.

Post-development baking may be carried out in the air atmosphere. From the viewpoint of further reducing the residual water in the resist pattern, however, post-development baking is preferably carried out in an inert gas atmosphere such as nitrogen, argon or the like, more preferably in a nitrogen atmosphere.

<Temperature of Post-Development Baking>

The temperature of post-development baking needs to be 200° C. or higher, more preferably 210° C. or higher, and even more preferably 220° C. or higher, but preferably 400° C. or lower, more preferably 350° C. or lower, even more preferably 280° C. or lower, particularly preferably 260° C. or below, and most preferably 250° C. or below. If the temperature of post-development baking is lower than 200° C., the residual water and residual organic component in the resist pattern cannot be sufficiently reduced. On the other hand, when the temperature of post-development baking is 400° C. or lower, it is possible to allow the resist pattern to maintain a good reverse taper shape in cross section by limiting thermal shrinkage of the resist pattern.

<Post-Development Baking Time>

The post-development baking time is preferably 10 minutes or more, more preferably 20 minutes or more, and even more preferably 30 minutes or more, but preferably 240 minutes or less, more preferably 180 minutes or less, and even more preferably 120 minutes or less. When the post-development baking time is 10 minutes or more, the residual water and residual organic component in the resist pattern can be further reduced. On the other hand, when the post-development baking time is 240 minutes or less, it is possible to allow the resist pattern to maintain a good reverse taper shape in cross section by limiting thermal shrinkage of the resist pattern.

### EXAMPLES

The present disclosure will be described in detail below based on Examples, which however shall not be construed as limiting the scope of the present disclosure.

In Examples and Comparative Examples, residual water, residual organic component, presence of abnormal protrusions on sidewalls, and heat deterioration resistance upon post-development baking of a resist pattern were evaluated in the manners described below. The results of the evaluations are shown in Table 1.

<Residual Water>

For the resist patterns formed in accordance with Examples and Comparative Examples, after raising the temperature from room temperature to 350° C., heating was performed for 60 minutes by maintaining the temperature at 350° C. The gas component generated from the resist pattern was measured with a thermal desorption spectrometer (WA1000S/W, manufactured by ESCO Ltd.). The mass (μg) of water was determined from the peak area value of detected water and was divided by the mass (g) of the resist pattern before heating to calculate a water content per unit mass (μg/g), which was evaluated based on the criteria given below.

A: Water content per unit mass was less than 3,000 μg/g

B: Water content per unit mass was 3,000 μg/g or more and less than 8,000 μg/g

C: Water content per unit mass was 8,000 μg/g or more and less than 9,000 μg/g

D: Water content per unit mass was 9,000 μg/g or more

### <Residual Organic Component>

For the resist patterns formed in accordance with Examples and Comparative Examples, after raising the temperature from room temperature to 230° C. while passing high-purity nitrogen gas through the heating oven, heating was performed for 60 minutes. The gas component generated from the resist pattern was collected in an adsorption tube. The collected component was measured by a gas chromatograph-mass spectrometer (GC-MS). Using a calibration curve of decane standard substance, the mass (μg) of an organic component was determined from the peak area value of the detected organic component and was divided by the mass (g) of the resist pattern before heating to calculate an organic component content per unit mass (μg/g), which was evaluated based on the criteria given below.

A: Organic component content per unit mass was less than 1,000 μg/g

B: Organic component content per unit mass was 1,000 μg/g or more and less than 3,000 μg/g

C: Organic component content per unit mass was 3,000 μg/g or more and less than 5,000 μg/g

D: Organic component content per unit mass was 5,000 μg/g or more

### <Presence of Abnormal Protrusions on Sidewalls)

The resist patterns formed in accordance with Examples and Comparative Examples were cut at an arbitrary position and arbitrary three points on the cross section of each resist pattern were observed using a scanning electron microscope at 5,000×. The presence of any abnormal protrusion protruding from sidewalls of the resist pattern was checked and evaluated based on the criteria given below.

A: Abnormal protrusion was observed

B: Abnormal protrusion was not observed

### <Heat Deterioration Resistance Upon Post-Development Baking>

Developed patterns before post-development baking were cut at an arbitrary position and arbitrary three points on the cross section of each developed pattern were observed using a scanning electron microscope at 5,000× to measure a line width L0 (average of the line widths at the three arbitrary points) of the developed pattern before post-development baking. Next, resist patterns after post-development baking were cut at an arbitrary position and arbitrary three points on the cross section of each resist pattern were observed using a scanning electron microscope at 5,000× to measure a line width L1 (average of the line widths at the three arbitrary points) of the resist pattern after post-development baking. % Line width shrinkage (=(L0−L1)/L0×100) was calculated from the L0 and L1. Using the % line width shrinkage and the state of the observed cross-sectional shape of the resist pattern after post-development baking (i.e., whether a reverse taper shape is maintained), evaluations were made based on the criteria given below.

A: Reverse taper shape was maintained, with % line width shrinkage of less than 5%

B: Reverse taper shape was maintained, with % line width shrinkage of 5% or more and less than 10%

C: Reverse taper shape was not maintained, and/or, % line width shrinkage was 10% or more

### Example 1

### <Preparation of Resin Liquid>

60 parts by mass of polyvinyl phenol resin (Maruka Linker S-2P, manufactured by Maruzen Petrochemical Co., Ltd., poly p-vinylphenol, weight-average molecular weight=5,000) and 40 parts by mass of novolac resin (weight-average molecular weight=4,000, prepared by dehydration condensation of metacresol/paracresol (70/30 by mass for preparation) with formaldehyde) as alkali-soluble resins; 2 parts by mass of a halogen-containing triazine compound (TAZ 110, manufactured by Midori Kagaku Co., Ltd.,) as a photoacid generator; 20 parts by mass of hexamethoxymethylmelamine (CYMEL 303, manufactured by Mitsui Cytec Co., Ltd.,) as an acid-catalyzed cross-linker; 1 part by mass of a bisazide compound (BAC-M, manufactured by Toyo Gosei Co., Ltd.) as an actinic radiation absorbing compound; and 0.5 parts by mass of triethanolamine (boiling point=335° C.) as a nitrogen-containing basic compound were added and dissolved in 290 parts of propylene glycol monomethyl ether acetate (PGMEA) as an organic solvent. The obtained solution was filtered through a polytetrafluoroethylene membrane filter with a pore size of 0.1 μm to prepare a resin liquid having a solid content concentration of 30% by weight.

### <Formation of Resist Pattern>

The resin liquid obtained above was applied onto a silicon wafer using a spin coater. The silicon wafer having a coating film formed thereon was heated on a hot plate at 110° C. for 90 seconds (pre-exposure baking) to afford a radiation-sensitive resin film having a thickness of 3 μm. Through a mask having a 20 μm line & space (L & S) pattern, the radiation-sensitive resin film was exposed using an exposure device (PLA 501F, manufactured by Canon Inc., UV light source, irradiation wavelength=365 nm to 436 nm). The exposure dose was adjusted such that the ratio of line and space portions was 1:1. After exposure, post-exposure baking was carried out on a hot plate under the condition of 110° C. for 60 seconds to form a cured film.

The obtained cured film was subjected to paddle development for 70 seconds with an alkaline developer (38% by mass aqueous tetramethylammonium hydroxide solution) to afford a developed pattern of lines and spaces on the silicon wafer.

The obtained developed pattern on the silicon wafer was subjected to post-development baking at 230° C. in the air atmosphere using an oven to afford a resist pattern. A cross section of the obtained resist pattern had a good reverse taper shape.

### Example 2

A resin liquid was prepared and a resist pattern was formed as in Example 1 except that when forming the resist pattern, post-development baking was carried out in a nitrogen atmosphere.

### Examples 3, 8 and 9

Resin liquids were prepared and resist patterns were formed as in Example 1 except that when forming the resist patterns, the temperature of the post-development baking was changed as shown in Table 1.

### Examples 4 and 6

Resin liquids were prepared and resist patterns were formed as in Example 1 except that when preparing the resin liquids, the blending amounts of the polyvinyl phenol resin and novolac resin were changed as shown in Table 1.

### Examples 5 and 7

Resin liquids were prepared and resist patterns were formed as in Example 1 except that when preparing the resin liquids, the blending amounts of the polyvinyl phenol resin and novolac resin were changed as shown in Table 1 and that when forming the resist patterns, post-development baking was carried out in a nitrogen atmosphere.

### Comparative Examples 1 to 3 and 5

Resin liquids were prepared and resist patterns were formed as in Example 1 except that when preparing the resin liquids, the blending amounts of the polyvinyl phenol resin and novolac resin were changed as shown in Table 1.

### Comparative Examples 4 and 6

Resin liquids were prepared and resist patterns were formed as in Example 1 except that when preparing the resin liquids, the blending amounts of the polyvinyl phenol resin and novolac resin were changed as shown in Table 1 and that when forming the resist patterns, post-development baking was carried out in a nitrogen atmosphere.

### Comparative Example 7

A resin liquid was prepared and a resist pattern was formed as in Example 1 except that when forming the resist pattern, the temperature of post-development baking was changed as shown in Table 1.

TABLE 1

| | | | | Ex. 1 | Ex. 2 | Ex. 3 | Ex. 4 | Ex. 5 |
|---|---|---|---|---|---|---|---|---|
| Resin liquid | Alkali-soluble | Polyvinyl phenol resin (parts by mass) | | 60 | 60 | 60 | 80 | 80 |
| | resin | Novolac resin (parts by mass) | | 40 | 40 | 40 | 20 | 20 |
| | Cross-linker | Photoacid | Halogen-containing triazine | 2 | 2 | 2 | 2 | 2 |
| | component | generator | compound (parts by mass) | | | | | |
| | | Acid- | Hexamethoxymethylmelamine | 20 | 20 | 20 | 20 | 20 |
| | | sensitive | (parts by mass) | | | | | |
| | | cross- | | | | | | |
| | | linker | | | | | | |
| | Actinic | Bisazide compound (parts by mass) | | 1 | 1 | 1 | 1 | 1 |
| | radiation absorbing | | | | | | | |
| | compound | | | | | | | |
| | Organic solvent | PGMEA (parts by mass) | | 290 | 290 | 290 | 290 | 290 |
| | Other component | Nitrogen- | Triethanolamine | 0.5 | 0.5 | 0.5 | 0.5 | 0.5 |
| | | containing | (parts by mass) | | | | | |
| | | basic | | | | | | |
| | | compound | | | | | | |
| Post- | Temperature (° C.) | | | 230 | 230 | 250 | 230 | 230 |
| development | Atmosphere | | | Air | Nitrogen | Air | Air | Nitrogen |
| baking | | | | Atmosphere | Atmosphere | Atmosphere | Atmosphere | Atmosphere |
| Evaluations | Residual water | | | B | A | B | B | A |
| | Residual organic component | | | A | A | A | A | A |
| | Presence of abnormal protrusions on sidewalls | | | A | A | A | A | A |
| | Heat deterioration resistance upon post-development baking | | | A | A | A | A | A |
| | | | | | | | | Comp. |
| | | | | Ex. 6 | Ex. 7 | Ex. 8 | Ex. 9 | Ex. 1 |
| Resin liquid | Alkali-soluble | Polyvinyl phenol resin (parts by mass) | | 40 | 40 | 60 | 60 | 30 |
| | resin | Novolac resin (parts by mass) | | 60 | 60 | 40 | 40 | 70 |
| | Cross-linker | Photoacid | Halogen-containing triazine | 2 | 2 | 2 | 2 | 2 |
| | component | generator | compound (parts by mass) | | | | | |
| | | Acid- | Hexamethoxymethylmelamine | 20 | 20 | 20 | 20 | 20 |
| | | sensitive | (parts by mass) | | | | | |
| | | cross- | | | | | | |
| | | linker | | | | | | |
| | Actinic | Bisazide compound (parts by mass) | | 1 | 1 | 1 | 1 | 1 |
| | radiation absorbing | | | | | | | |
| | compound | | | | | | | |
| | Organic solvent | PGMEA (parts by mass) | | 290 | 290 | 290 | 290 | 290 |
| | Other component | Nitrogen- | Triethanolamine | 0.5 | 0.5 | 0.5 | 0.5 | 0.5 |
| | | containing | (parts by mass) | | | | | |
| | | basic | | | | | | |
| | | compound | | | | | | |

| | | | | | | |
|---|---|---|---|---|---|---|
| Post- | Temperature (° C.) | 230 | 230 | 200 | 300 | 230 |
| development | Atmosphere | Air | Nitrogen | Air | Air | Air |
| baking | | Atmosphere | Atmosphere | Atmosphere | Atmosphere | Atmosphere |
| Evaluations | Residual water | C | B | C | B | D |
| | Residual organic component | B | B | C | A | B |
| | Presence of abnormal protrusions on sidewalls | A | A | A | A | A |
| | Heat deterioration resistance upon post-development baking | B | B | A | B | B |

| | | | | Comp. | Comp. | Comp. | Comp. | Comp. | Comp. |
|---|---|---|---|---|---|---|---|---|---|
| | | | | Ex. 2 | Ex. 3 | Ex. 4 | Ex. 5 | Ex. 6 | Ex. 7 |
| Resin liquid | Alkali-soluble | Polyvinyl phenol resin (parts by mass) | | 20 | — | — | 100 | 100 | 60 |
| | resin | Novolac resin (parts by mass) | | 80 | 100 | 100 | — | — | 40 |
| | Cross-linker | Photoacid | Halogen-containing triazine | 2 | 2 | 2 | 2 | 2 | 2 |
| | component | generator | compound (parts by mass) | | | | | | |
| | | Acid- | Hexamethoxymethylmelamine | 20 | 20 | 20 | 20 | 20 | 20 |
| | | sensitive | (parts by mass) | | | | | | |
| | | cross- | | | | | | | |
| | | linker | | | | | | | |
| | Actinic | Bisazide compound (parts by mass) | | 1 | 1 | 1 | 1 | 1 | 1 |
| | radiation absorbing | | | | | | | | |
| | compound | | | | | | | | |
| | Organic solvent | PGMEA (parts by mass) | | 290 | 290 | 290 | 290 | 290 | 290 |
| | Other component | Nitrogen- | Triethanolamine | 0.5 | 0.5 | 0.5 | 0.5 | 0.5 | 0.5 |
| | | containing | (parts by mass) | | | | | | |
| | | basic | | | | | | | |
| | | compound | | | | | | | |

| | | | | | | | |
|---|---|---|---|---|---|---|---|
| Post- | Temperature (° C.) | 230 | 230 | 230 | 230 | 230 | 180 |
| development | Atmosphere | Air | Air | Nitrogen | Air | Nitrogen | Air |
| baking | | At- | At- | At- | At- | At- | At- |
| | | mosphere | mosphere | mosphere | mosphere | mosphere | mosphere |
| Evaluations | Residual water | D | D | D | — | — | C |
| | Residual organic component | B | B | B | — | — | D |
| | Presence of abnormal protrusions on sidewalls | A | A | A | B | B | A |
| | Heat deterioration resistance upon post-development baking | A | B | B | — | — | A |

It can be seen from Table 1 that Examples 1 to 9, wherein a resin liquid containing an alkali-soluble resin which comprises 35% by mass or more and 90% by mass or less of a polyvinyl phenol resin was used and post-development baking was carried out at 200° C. or higher, succeeded in forming a resist pattern having sufficiently reduced amounts of residual water and residual organic component and having a good reverse taper shape in cross section.

On the other hand, it can be seen from Table 1 that Comparative Examples 1 to 4, wherein an alkali-soluble resin which comprises less than 35% by mass of a polyvinyl phenol resin was used, failed to sufficiently reduce the residual water in the resist pattern.

It can also be seen from Table 1 that Comparative Examples 5 and 6, wherein an alkali-soluble resin which comprises 100% by mass of a polyvinyl phenol resin was used, resulted in protrusions observed on sidewalls of the resist pattern and thus failed to form a resist pattern having a good reverse taper shape in cross section.

Finally, it can be seen from Table 1 that Comparative Example 7 wherein post-development baking was carried out at lower than 200° C. failed to sufficiently reduce the residual organic component in the resist pattern.

### INDUSTRIAL APPLICABILITY

According to the present disclosure, it is possible to provide a method of forming a resist pattern, which enables formation of a resist pattern having a good reverse taper shape in cross section and having reduced amounts of residual water and residual organic component.

1. A method of forming a resist pattern, comprising:
forming a radiation-sensitive resin film using a resin liquid containing an alkali-soluble resin, a cross-linker component, and an organic solvent;
exposing the radiation-sensitive resin film to form a cured film;
developing the cured film to form a developed pattern; and
applying post-development baking on the developed pattern to provide a resist pattern,
wherein the alkali-soluble resin comprises 35% by mass or more and 90% by mass or less of a polyvinyl phenol resin, and a temperature of the post-development baking is 200° C. or higher.

2. The method of forming a resist pattern according to claim 1, wherein the temperature of the post-development baking is 400° C. or lower.

3. The method of forming a resist pattern according to claim 1, wherein the temperature of the post-development baking is 220° C. or higher.

4. The method of forming a resist pattern according to claim 1, wherein the post-development baking is carried out in an inert gas atmosphere.

5. The method of forming a resist pattern according to claim 4, wherein the inert gas is nitrogen.

6. The method of forming a resist pattern according to claim 1, wherein the resin liquid further comprises an actinic radiation absorbing compound.
